(19) United States
(12) Patent Application Publication
(10) Pub. No.: US 2001/0008983 A1
(43) Pub. Date: Jul. 19, 2001

(54) Carrier system for carrying objects, carrier unit constituting carrier system, and control system for carrier system

(75) Inventors: Tadashi Yotsumoto, Yokohama-shi (JP); Yuichi Kuroda, Yokohama-shi (JP)

Correspondence Address: OBLON, SPIVAK, McCLELLAND, MAIER & NEUSTADT, P.C., Fourth Floor, 1755 Jefferson Davis Highway, Arlington, VA, 22202, US

(73) Assignee: Kabushiki Kaisha Toshiba, Kawasaki-shi (JP)

(21) Appl. No.: 09/750,693

(22) Filed: Jan. 2, 2001

(30) Foreign Application Priority Data
Jan. 13, 2000 (JP) P2000-4782

(51) Int. Cl. H01L 21/68

(52) U.S. Cl. 700/230

(57) ABSTRACT

A carrier system is constituted by a plurality of carrier units which are coupled by inter-unit couplers. Each carrier unit includes a rail for moving a carrier, a table for placing an object to be delivered or retrieved, and a coupler for joining the rail and table. An inter-unit coupler is provided at the coupler. Further, the carrier system includes a rail having two rail tracks where two carriers move without interfering with each other.

### CROSS-REFERENCE TO RELATED APPLICATION

This application claims benefit of priority under 35 USC § 119 to Japanese Patent Application No. 2000-4782, filed on Jan. 13, 2000, the entire contents of which are incorporated by reference herein.

### BACKGROUND OF THE INVENTION

1. Field of the Invention

The present invention relates to a carrier unit, a carrier system, and a control system for the carrier system, and more particularly relates to a carrier system for delivering and retrieving objects, carrier units constituting such a carrier system, and a control system for controlling the carrier system. Further, the invention relates to a carrier system which is preferable to deliver and retrieve objects such as semiconductor wafer containers, and carrier units constituting such a carrier system, and a control system for controlling the carrier system.

2. Description of the Related Art

In a semiconductor manufacturing line, a carrier system is used in order to deliver and retrieve a semiconductor wafer container (or a semiconductor wafer carrier or a semiconductor wafer pot) to and from manufacturing devices. Each semiconductor wafer container houses a plurality of non-processed or processed semiconductor wafers.

Referring to FIG. 12 of the accompanying drawings, an existing carrier system 100 used in a semiconductor manufacturing line comprises: a rail 101; a plurality of carriers 103 moving on the rail 101 in order to deliver or retrieve semiconductor wafer containers 106; and tables 104 joined to manufacturing devices 105 which process semiconductor wafers.

The rail 101 extends over the tables 104 in a closed loop. As shown in FIGS. 13 and 14, the rail 101 is fixedly provided on a ceiling 102.

Each carrier 103 is constituted by: a carrier body 103A; a moving section 103B holding the carrier body 103A and moving on the rail 101; a grip 103E gripping the semiconductor wafer container 106; a lift 103C for moving the grip 103E up and down; and a bearer cable 103D extending between the lift 103C and the grip 103E. The carrier 103 is suspended from the rail 101 via the moving section 103B, and moves on the rail 101. The grip 103E delivers and retrieves the semiconductor wafer container 106 to and from the table 104. The semiconductor wafer container 106 houses non-processed or processed semiconductor wafers, and is delivered and retrieved to and from the table 104 by the lift 103C of the carrier 103.

Referring to FIG. 12, a plurality of carriers 103 are present on the rail 101, and are moved in the same direction in response to a varying delivery command issued by a control system, not shown, thereby delivering or retrieving the semiconductor wafer containers 106. When a first carrier 103 is being delivering or retrieving the semiconductor wafer 106, (i.e. it is staying at its destination), second and other carriers 103 behind the first carrier 103 are controlled to be immovable until the first carrier 103 completes its operation.

The manufacturing devices 105 may be a resist film applying device, an exposure device, a developing device, a cleaning device, an etching device, a film forming device or the like.

The foregoing carrier system 100 seems to suffer from the following problems. First of all, the rail 101 is fixedly provided on the ceiling of a room where the carrier system 100 is installed, and extends in a predetermined shape. Therefore, it is difficult to replace or increase the manufacturing devices 105, to change the layout thereof, and so on.

Secondly, during the initial use of the carrier system 100, it is necessary to accurately align all the tables 104 with respect to the rail 101, and position the manufacturing devices 105 with respect to the tables 104. This means a lot of time and labor necessary for operating the carrier system 100.

Thirdly, when the manufacturing devices 105 are replaced or increased, or when their layout is changed, it is necessary to accurately realign all the tables 104 with respect to the rail 101 and re-position the manufacturing devices 105 with respect to the tables. This requires a lot of time and labor in order to resume the operation of the carrier system 100.

Fourthly, if the tables 104 or manufacturing devices 105 are displaced with respect to the rail 101 due to an earthquake or the like, they should be re-positioned, which will take a lot of time and labor in order to resume the operation of the carrier system 100.

Finally, since the rail 101 extends in the shape of a closed loop, a second carrier 103 cannot get ahead a first carrier 103 at its destination, and has to remain stationary until the first carrier 103 restarts moving. As a result, carriers 103 have to accelerate or decelerate frequently, and may suffer from traffic jam, which would cause an increase in the delivery time of the semiconductor wafer containers 106. In other words, the semiconductor wafer containers 106 will suffer from reduced carrying efficiency. In order to overcome the foregoing problems, a plurality of rails 101 may be provided so that a plurality of carriers 103 are moved simultaneously. However, the installation of a plurality of rails 101 inevitably leads to enlargement of the space for the carrier system 100.

### SUMMARY OF THE INVENTION

The present invention has been contemplated in order to overcome the foregoing problems of the related art, and is intended to provide a carrier system and carrier units which can be operated at reduced time and labor.

A further object of the invention is to provide a carrier system and carrier units in which rails, tables, manufacturing devices and so on can be freely replaced or increased and of which layout can be freely changed at reduced cost and labor.

A still further object of the invention is to provide a carrier system and carrier units which can reduce time for delivering objects and which can deliver and retrieve the objects with an increased efficiency.

It is a still further object of the invention to provide a control system which can reduce delivery time of the foregoing carrier system and promote efficiency thereof.

A final object of the invention is to provide a carrier unit, a carrier system or a control system which can accomplish at least two of the foregoing objects.

According to a first feature of the invention, there is provided a carrier unit comprising at least: a rail for moving (or running) a carrier thereon and having a predetermined unit length; a table placing an object and facing the rail; and a coupler for joining the table to the rail. The term “the predetermined unit length” of the rail denotes a length appropriate for constituting the carrier system using carrier units.

In this carrier unit, the rail and tables are made integral using the coupler (they have been relatively positioned), so that it is not necessary to align them. This is effective in reducing time and labor necessary for their alignment.

In accordance with a second feature, there is provided a carrier system comprising: a plurality of carrier units each of which includes at least a rail for moving a carrier thereon and having a predetermined unit length, a table for placing an object and facing the rail, and a coupler for joining the table to the rail; and an inter-unit joint for joining the carrier units and rails.

The carrier is preferably provided with a grip for holding an object, and a lift for moving the grip up and down. Further, it is possible for the table to have a device-joint for connecting to a manufacturing device.

With the carrier system, the carrier units are joined using inter unit couplers, so that they can be easily and freely replaced, increased or arranged in different layouts. In such a case, it is not necessary to re-align the rails and tables of the carrier units which are integral, which is effective in reducing the time and labor when replacing, increasing or re-arrangement thereof, and improving work efficiency.

According to a third feature, there is provided a carrier system comprising: a rail including first rail track and second rail track which are independent; a first carrier moving on the first rail track; and a second carrier moving on the second rail track without interfering with the first carrier.

In this carrier system, at least the first or second carrier preferably includes a grip for holding an object and a lift for moving the grip up and down.

The rail includes the first rail track and the second rail track, and the first and second carriers move on their corresponding rails without interfering with each other. Therefore, the first and second carriers can move in a variety of manners, e.g. they can get ahead each other or move in opposite directions. Even when the first or second carrier stops, the other carrier can move. The carriers can be independently accelerated or decelerated without causing any traffic jam, which is effective in improving the delivery efficiency or work efficiency.

According to a fourth feature, there is provided a control system for a carrier system which comprises a rail including first rail track and second rail track which are independent, a first carrier moving on the first rail track, and a second carrier moving on the second rail track without interfering with the first carrier. Further, the control system comprises: a carrier position recognizing unit for recognizing positions of the first carrier on the first rail track and the second carrier on the second rail track; a destination recognizing unit for recognizing destinations of the carriers; a delivery time calculating unit for calculating a time for the first and second carriers to reach destinations thereof; and a carrier allocating unit for controlling the movement of the first or second carrier, which is advantageous on the basis of the calculated delivery time, to and from the destination.

With this control system, the first and second carriers are moved in accordance with one of the following procedures (1) to (5): (1) both the first and second carriers are moved in the same direction; (2) the first and second carriers are moved in opposite directions; (3) either the first or second carrier is dedicated for delivery while the other is dedicated for retrieval; (4) either the first or second carrier is used for urgent delivery while the other carrier is used for normal delivery; and (5) the first and second carriers are moved at different speeds.

This control system further comprises: a host computer for controlling the carrier position recognizing unit, destination recognizing unit, delivery time calculating unit and carrier allocating unit.

The control system can manage the operation of the carrier system in such a manner that the carriers can be quickly moved to their destinations. Therefore, the control system can improve the carrying efficiency and work efficiency of the carrier system.

### BRIEF DESCRIPTION OF THE DRAWINGS

FIG. 1 is a perspective view of a carrier system according to a first embodiment of the invention.

FIG. 2 is a side elevation of the carrier system of FIG. 1.

FIG. 3 schematically shows a layout of the carrier system of FIG. 1.

FIG. 4(A) and FIG. 4(B) schematically show layouts of the carrier system of FIG. 1 in which some modifications are made.

FIG. 5 is a perspective view of a carrier system according to a second embodiment, schematically showing a layout thereof.

FIG. 6 is a sectional view of the carrier system, showing essential parts thereof.

FIG. 7 is a perspective view of a carrier used in the carrier system of FIG. 6.

FIG. 8(A) is a perspective view of essential parts of a rail used in the carrier system of FIG. 5-FIG. 7.

FIG. 8(B) is a cross section of the rail, taken along line F8B-F8B in FIG. 8(A).

FIG. 9 is a block diagram of a data network of a control system used for the carrier system according to the second embodiment.

FIG. 10 is a block diagram showing data flow in the control system of FIG. 9.

FIG. 11 is a flowchart of the control system of FIG. 9.

FIG. 12 is a perspective schematically showing the overall configuration of a carrier system of the related art.

FIG. 13 is a perspective view of essential parts of the carrier system of FIG. 12.

FIG. 14 is a sectional view of the essential parts of the carrier system of FIG. 12.

### DETAILED DESCRIPTION OF THE PREFERRED EMBODIMENTS

The invention will be described with reference to the preferred embodiments shown in the drawings. In the following embodiments, it is assumed that the carrier unit, carrier system and control system are applied to a semiconductor manufacturing line.

### FIRST EMBODIMENT OF THE INVENTION

[Structure of Carrier System and Carrier Unit]

Referring to FIG. 3, a carrier system 1 comprises a plurality of carrier units 10(1), 10(2), 10(3), . . . , 10(n-1) and 10(n), and a plurality of inter-unit couplers 20 for joining rails 11 of the carrier units 10(1) to 10(n). Each of the carrier units 10(1) to 10(n) includes at least: a rail 11 for moving a carrier 13 having a unit length; a table 14 for placing an object 16 to be delivered and provided below the rail 11; and a coupler 12 for connecting the table 14 to the rail 11. All of the carrier units 10(1) to 10(n) are substantially identical.

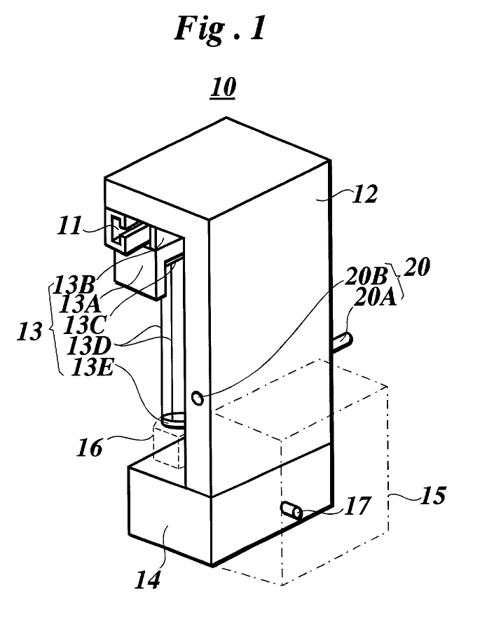

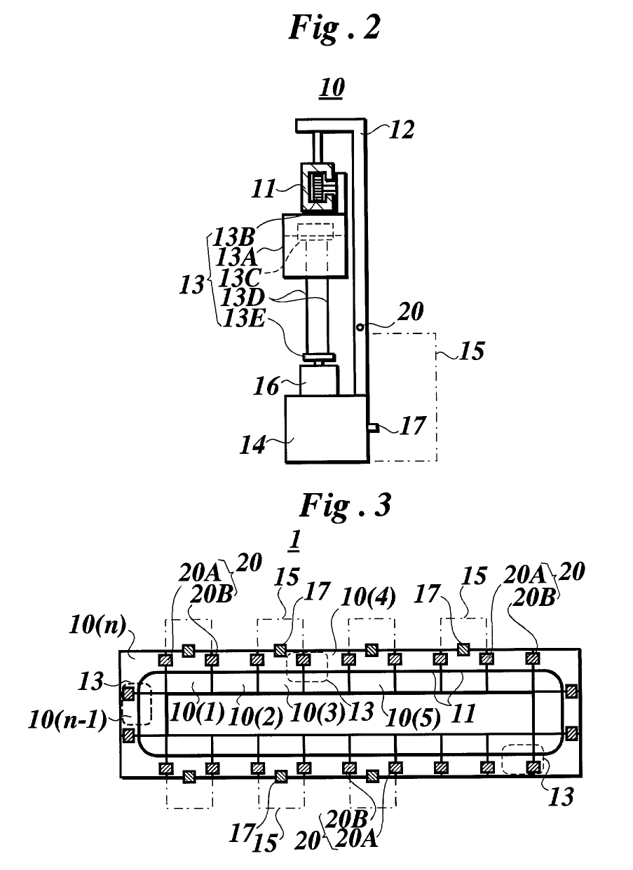

In each of the carrier units 10(1) to 10(n), the carrier 13 moves on the rail 11 in order to deliver or retrieve an object 16 to or from the table 14. The rail 11 is in the shape of letter “C” as shown in FIGS. 1 and 2, and is fixedly attached under one side of the coupler 12. The rail 11 is arranged on the table 14. Each rail 11 has a length which is appropriate for a unit configuration of the carrier system 1, and is preferably equal to a width of the table 14 or a width of the manufacturing device 15 connected to the table 14. In the carrier system 1 shown in FIG. 3, the carrier units 10(1) to 10(n) are sequentially arranged and connected, so that their rails 11 extend in the shape of a closed loop.

Each table 14 receives the object 16 which is delivered or retrieved by the carrier 13. In this embodiment, the object 16 is a semiconductor wafer container (i.e. a wafer carrier or a wafer pot) which houses a plurality of non-processed or processed semiconductor wafers.

Manufacturing devices 15 are connected to particular carrier units 10(1), 10(3) and so on via device-joints 17. The manufacturing devices 15 may be a resist applying device, an exposure device, a developing device, a cleaning device, an etching device, a film forming device and so on. Each of the manufacturing devices 15 includes a loader for delivering the object 16, i.e. non-processed semiconductor wafers, to a processing section from the table 14. Further, the manufacturing device 15 processes the semiconductor wafers as predetermined, and returns using an unloader the processed semiconductor wafers in into the semiconductor wafer container on the table 14.

The term “process the semiconductor wafers as predetermined” means the following. For example, the resist applying devices applies a photoresist film onto the semiconductor wafer, and the exposure device forms a latent image having a predetermined pattern to the photoresist film on the semiconductor wafer.

The tables 14 of the carrier units 10(2), 10(4) and so on except for the foregoing particular carrier units simply interconnect these particular carrier units 10 (1), 10(3) and so on.

The coupler 12 is made of a frame in the shape of inverted letter L, is provided with the rail 11 at an upper side thereof, and is fixedly attached to the table 14 using small screws, bolts and nuts, and so on which are detachable and strong, or is welded to the table 14 as an integral part.

Inter-unit couplers 20 extend between two adjacent carrier units 10(1) to 10(n). Each inter-unit coupler 20 includes a first coupler 20A of gibbosity and a second coupler 20B of trough, both of which are arranged at opposite sides of the coupler 12. For example, the first coupler 20A of the carrier unit 10(1) is joined to the second coupler 20B of the carrier unit 10(n), thereby positioning the carrier units 10(1) and 10(n). The second coupler 20B of the carrier unit 10(1) is joined to the first coupler 20A of the carrier unit 10(2), thereby positioning the carrier units 10(1) and 10(2). In other words, when these carrier units are joined via the inter-unit couplers 20, the rails 11 of the carrier units 10(1) to 10(n) are mutually connected, thereby extending in the shape of a closed loop.

In the carrier system 1, the rails 11 of the carrier units 10(1) to 10(n) are joined when these carrier units are connected using the inter unit couplers 20. Alternatively, the rails 11 of the carrier units 10(1) to 10(n) may be directly joined by inter-unit couplers 20.

Each carrier 13 includes: a carrier body 13A; a moving part 13B moving on the rail 11; a grip 13E holding the object 16; a lift 13C moving the grip 13E up and down; and a bearer cable 13D extending between the lift 13C and the grip 13E, as shown in FIGS. 1 and 2. The carrier 13 is suspended from the rail 11 via the moving part 13B, and moves on the rail 11.

The moving part 13B is preferably a rubber roller or a metal roller. The rubber roller can suppress vibrations or noise of the moving carrier 13 while the metal roller can prolong the life span of the moving part 13B. The grip 13E actually delivers or retrieves the object 16 to or from the table 14 while the carrier 13 remains stationary. The lift 13C is provided with a reel (not shown) for taking up the bearer cable 13D and an electric motor for controlling the rotation of the reel.

[First Modified Example of Carrier System ]

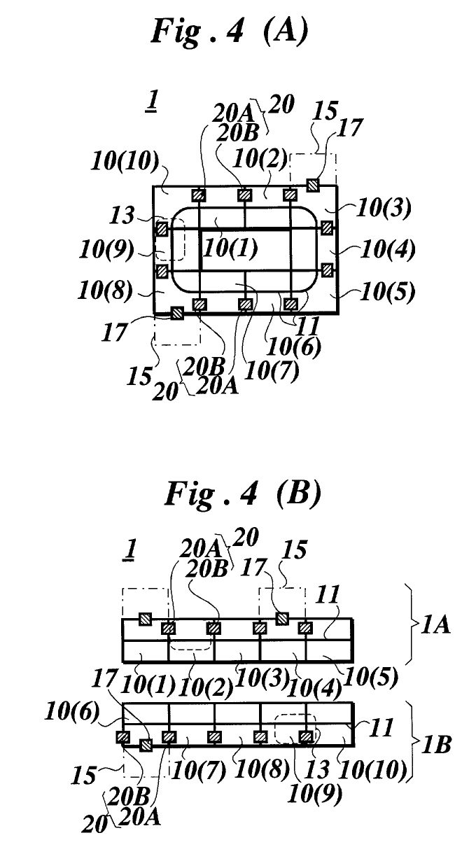

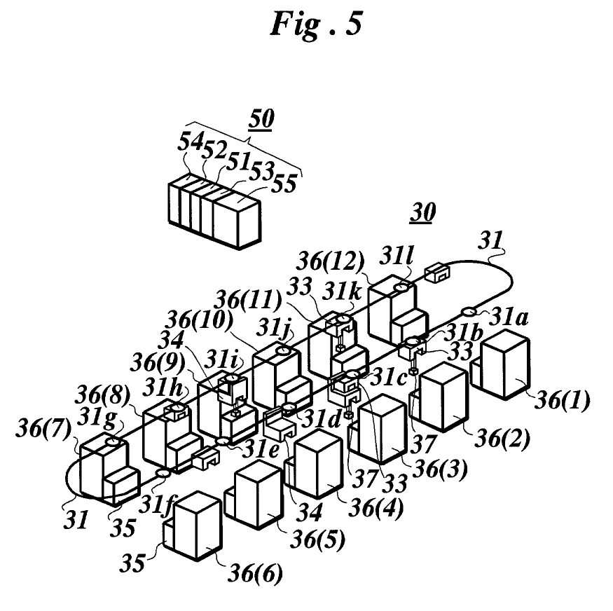

In the carrier system 1 shown in FIG. 4(A), the carrier units 10(1) to 10(n) are arranged such that their rails 11 extend in the shape of a closed loop, thereby forming a semiconductor manufacturing line. In this example, the carrier units 10(1) to 10(n) are joined by the inter-unit couplers 20. Further, the carrier units 10(3) and 10(8) are connected to the manufacturing devices 15 via the device-joints 17. The carrier 13 travels on the rails 11 of the carrier units 10(1) to 10(10).

Referring to FIG. 4(A), the object 16, i.e. the semiconductor wafer container housing non-processed semiconductor wafers, is delivered to the table 14 of the carrier unit 10(3), where the semiconductor wafers are processed. Thereafter, the processed semiconductor wafers are retrieved into the semiconductor wafer container, which is delivered to the carrier unit 10(8).

[Second Modified Example of Carrier System]

A carrier system 1 shown in FIG. 4(B) includes a carrier unit block 1A having carrier units 1(1) to 10(5) and another carrier unit block 1B having carrier units 1(6) to 1(10). In the carrier unit block 1A, the carrier units 10(1) to 10(5) are connected by inter-unit couplers 20, and the rails 11 extend straight. As a result, the carrier 13 reciprocates on the straight rails 11. The carrier units 10(1) and 10(4) are joined to the manufacturing devices 15 via the device-joint 17.

The carrier unit block 1B is configured identically to the carrier unit block 1A, so that the carrier 13 reciprocates on the straight rails 11. In the carrier unit block 1B, the carrier units 10(6) to 10(10) are connected by inter-unit couplers 20, and the rails 11 extend straight. The carrier unit 10(6) is joined to the manufacturing device 15 via the device-joint 17.

The carrier unit blocks 1A and 1B are separately controlled with respect to their operations. For example, in the carrier unit block 1A, the object 16 is delivered to the table 14 of the carrier unit 10(1), is processed by the manufacturing device 15, is returned to the table 14, and is then delivered to the carrier unit 10(4). In the carrier unit block 1B, the object 16 is delivered to the table 14 of the carrier unit 10(6), is processed by the manufacturing device 15, is returned to the table 14, and is finally retrieved by the carrier 13.

[Third Modified Example of Carrier System ]

In the layouts shown in FIGS. 4(A) and 4(B), the carrier system 1 may form small semiconductor manufacturing lines. The small semiconductor manufacturing lines are combined in order to constitute a large semiconductor manufacturing line. For instance, the carrier systems 1 are used to form a photolithography line (for photo resist film application, exposure, development and so on), an etching line, and a film forming line. Then, these pre-processing lines will be combined to constitute a large semiconductor manufacturing line.

Further, the carrier systems 1 will be used for form a small pre-processing line and a small post-processing line for packaging, for example, which will be combined to constitute a large semiconductor manufacturing line including the pre- processing and post-processing lines.

In each carrier unit 10 of the carrier system 1, the rail 11 and table 14 are joined as an integral part using the coupler 12, so that no further alignment is necessary for them. Therefore, the carrier units 12, manufacturing devices 15 and so on can be easily replaced, increased or rearranged without any positioning, which leads to reduced labor and time necessary for positioning.

In the first embodiment, the carrier units 10(1) to 10(n) are joined using the inter-unit couplers 20, so that they can be easily replaced, increased or rearranged as desired. As a result, the carrier system 1 can start its initial operation in a shortened period of time since no alignment is necessary for the tables 14 and rails 11. Further, the carrier system 1 can resume its operation quickly even when the carrier units 10, manufacturing devices 15 or the like are replaced, increased or rearranged, which is effective in improving the work efficiency.

Further, since the rail 11 and table 14 are made integral using the coupler 12, they will not be displaced with each other even if the carrier system 1 swings due to an unexpected accident such as an earthquake. In such a case, the carrier system 1 can resume its operation shortly without reducing its work efficiency.

According to the first embodiment, the rails 11 are provided above the tables 14 of the carrier units 10, and the carrier 13 movably hangs from the rails 11. Alternatively, the carrier 13 may be moved on side surfaces of the rails 11, or actually on the upper surface of the rails 11. Further, the rails 11 may be attached along the side surfaces of the tables 14, or the tables 14 may be provided above the rails 11.

### SECOND EMBODIMENT OF THE INVENTION

In a second embodiment, carriers of a carrier system 30 are modified in order to improve delivery efficiency.

[Structure and Carrier System and Carrier Units]

Referring to FIGS. 5 to 7, the carrier system 30 includes: a rail 31 having a first rail track 311 and a second rail track 312 which are parallel; afirst carrier 33 moving (or traveling) on the first rail track 311; and second carriers 34 moving (or traveling) on the second rail track 312 without interfering with the first carriers 33. Tables 35 are provided directly below destinations 31a, 31b, 31c, . . . , 31l along the rail 31, and are connected to manufacturing devices 36(1) to 36(12).

The carrier system 30 is controlled by a control system 50, which is constituted by a host computer 55 for controlling the overall operation of a carrier position recognizing unit 51 for recognizing positions of the first and second carriers 33 and 34 on the first and second rail tracks 311 and 312, a delivery point recognizing unit 52 for recognizing the delivery points 31a to 32l, a delivery time calculating unit 53 for calculating delivery times of the first and second carriers 33 and 34 to the destinations 31a to 32l, and a carrier allocating unit for controlling the operation of the first or second carrier 33 or 34 which is advantageous on the basis of the calculated delivery time.

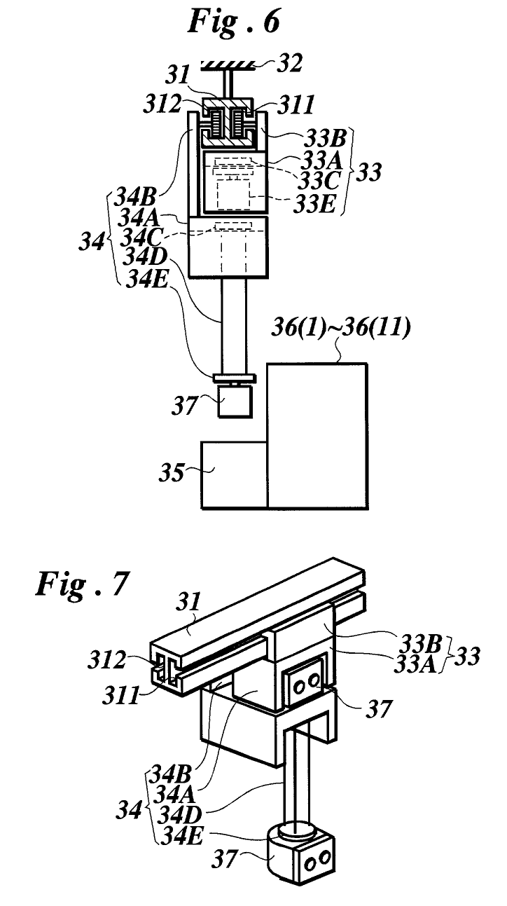

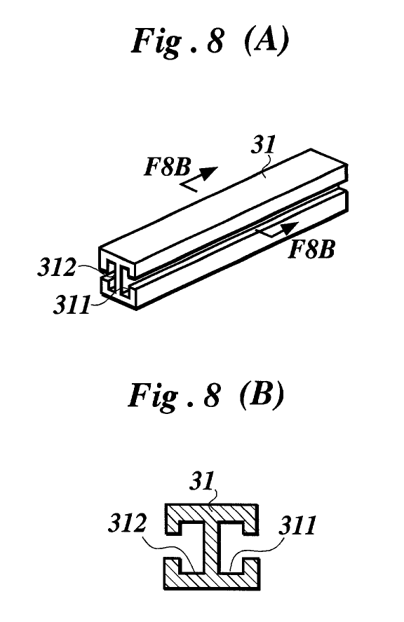

The rail 31 extends over the tables 35 to which the manufacturing devices 36(1) to 36(12) are connected, so that the first and second carriers 33 and 34 move on the rail 31 above the tables 35. The first and second carriers 33 and 34 deliver and retrieve objects 37 to and from the tables 35. Referring to FIGS. 6, 7, 8(A) and 8(B), the first and second rail tracks 311 and 312 of the rail 31 are made of guide rails in the shape of letter C, and are made integral.

The rail 31 is fixedly provided on a ceiling 32 of a room (such as a clean room) where the carrier system 30 is installed, and extends in the shape of a closed loop.

Each table 35 holds the object 37 which is delivered or retrieved by the first or second carrier 33 or 34. The object 37 is a semiconductor wafer container similarly to the object 16 in the first embodiment, and house non-processed or processed semiconductor wafers.

The tables 35 are connected to the manufacturing devices 36(1) to 36(12) via the device-joints, not shown. These manufacturing devices are similar to the manufacturing devices 15 in the first embodiment.

As shown in FIGS. 6 and 7, the first carrier 33 is positioned just under the rail 31 and above the second carrier 34, and includes a carrier body 33A, a moving part 33B for supporting the carrier body 33A and moving on the first rail track 311, a grip 33E for holding the object 37, a lift 33C moving the grip 33E up and down, and a bearer cable (not shown) for connecting the lift 33C and grip 33E. Specifically, the first carrier 33 moves on the first rail track 311 via the moving part 33B, which is preferably a rubber or metal roller. The grip 33E detachably holds the object 37 on the table 35. Delivery or retrieval of the object 37 is actually performed by the lift 33C while the first carrier 33 stays above the table 35 (one of the destinations 31a to 31l). The bearer cable is identical to the bearer cable 13D in the first embodiment. The lift 33C has at least a reel and an electric motor.

The second carrier 34 is positioned just under the first carrier 33, i.e. it is present below the rail 31 via the first carrier 33, and moves without interfering with the first carrier 33. The second carrier 34 is essentially identical to the first carrier 33, and has a carrier body 34A, a moving part 43B for supporting the carrier body 34A and moving on the second rail track 312 of the rail 31, a grip 34E for holding the object 37, a lift 34C moving the grip 34E up and down, and a bearer cable (not shown) for connecting the lift 34C and grip 34E. The second carrier 34 is suspended from the second rail track 312 via the moving section 34B having a long vertical part, and moves on the second rail track 312. The moving section 34B is made of a material identical to that of the moving section 33B. The grip 34E detachably holds the object 37 on the table 35. Delivery and retrieval of the object 37 are performed by the lift 34C while the second carrier 34 stays above the table 35 (at one of the destinations 31a to 32l). The bearer cable 34D is identical to the bearer cable 13D of the first embodiment. The lift 34C has at least a reel and an electric motor.

With the carrier system 30, the rail 31 includes the first and second rail tracks 311 and 312 where the first and second carriers 33 and 34 move without interfering with each other. The first and second carriers 33 and 34 operate in the following modes.

(a) The first and second carriers 33 and 34 are moved in the same direction. Even if either the first or second carrier 33 or 34 remains stationary at the destination, the other carrier can get ahead of it.

(b) The first and second carriers 33 and 34 are moved in opposite directions.

(c) Either the first or second carrier 33 or 34 is dedicated for delivery while the other carrier is dedicated for retrieval.

(d) Either the first or second carrier 33 or 34 is used for urgent delivery while the other carrier is dedicated for normal delivery.

(e) The first and second carriers 33 and 34 are independently accelerated or decelerated.

[Configuration of Control System for Carrier System]

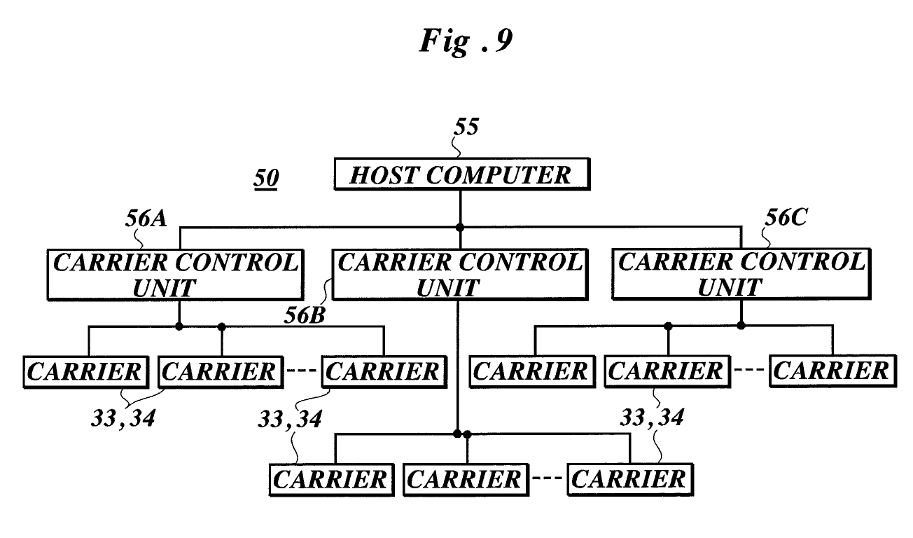

Referring to FIG. 9, the control system 50 includes carrier control units 56A to 56C, each of which mainly controls the first and second carriers 33 and 34 belong to each section of the semiconductor manufacturing line such as an etching section, film forming section and so on. The carrier control units 56A to 56C are controlled by the host computer 55.

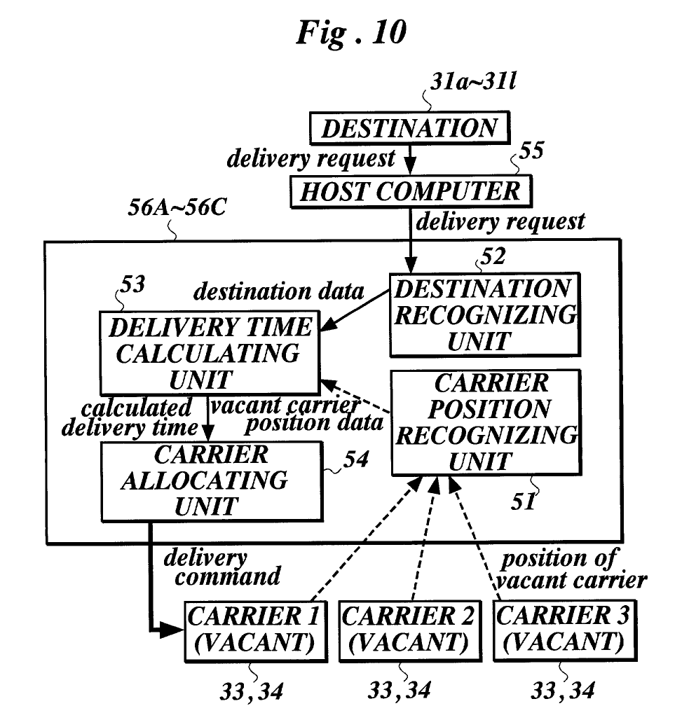

Referring to FIG. 10, each of the carrier control units 56A to 56C includes a carrier position recognizing unit 51, a destination recognizing unit 52, a delivery time calculating unit 53, and a carrier allocating unit 54. The carrier position recognizing unit 51 and carrier allocating unit 54 are connected to the first and second carriers 33 and 34. The carrier position recognizing unit 51 is also connected to the destinations 31a to 32l via the host computer 55.

[Control Operation of Control System ]

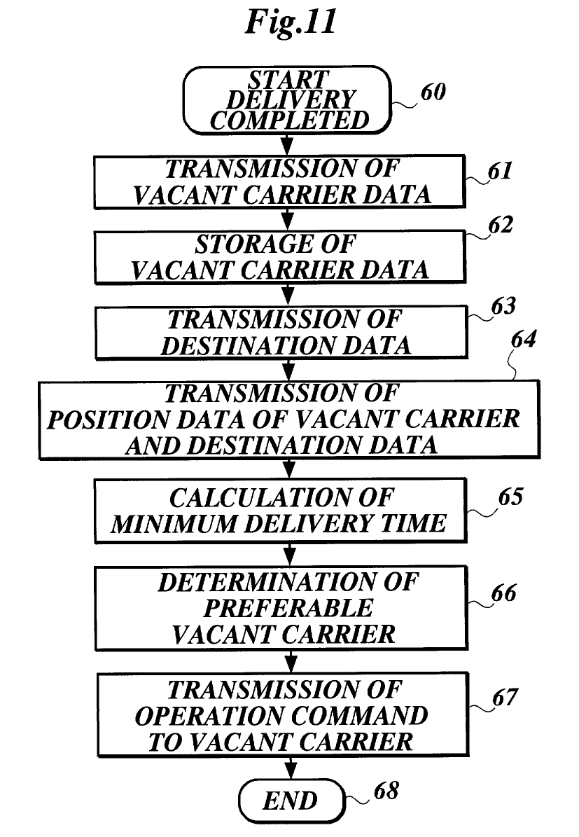

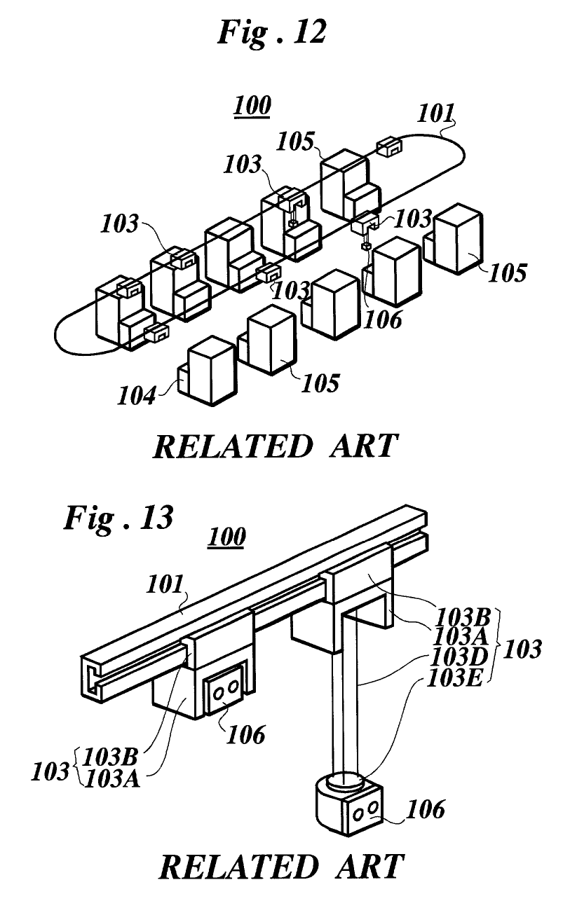

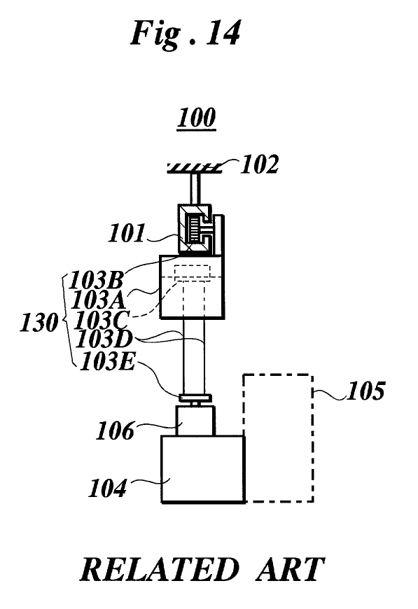

The operation of the control system 50 will be described with reference to a control flowchart of FIG. 5 to FIG. 11.

(1) When the object 37 is delivered to any of the destinations 31a to 32l along the rail 31 (step 60), the vacant first and second carriers 33 and 34 transmits vacant state data concerning at least their identification codes and current positions to the carrier position recognizing unit 51 of any of the carrier control units 56A to 56C (step 61). The carrier position recognizing unit 51 continuously stores the vacant state data (step 62).

(2) If a delivery request is made from one of the destinations 31a to 32l, e.g. the destination 31a, position data of the destination 31a are transmitted to the destination recognizing unit 52 via the host computer 55 on the on-line basis (step 63).

(3) The carrier position recognizing unit 51 provides the delivery time calculating unit 53 with the position data of the vacant first and second carriers 33 and 34. Further, the destination recognizing unit 52 sends the data of the destination 31a to the delivery time calculating unit 53 (step 64).

(4) In step 65, the delivery time calculating unit 53 calculates minimum delivery times from the destination 31a to a succeeding destination on the basis of the position data of the vacant first and second carriers 33 and 34, the data of the destination 31a that has made the delivery request, speeds, acceleration, deceleration and moving directions of the carriers 33 and 34, and so on.

(5) The carrier allocating unit 54 compares the calculated minimum delivery times of the first and second carriers 33 and 34, and determines which the first or second carrier 33 or 34 should be preferentially moved (step 66). The carrier allocating unit 54 reserves the first or second carrier 33 or 34 whichever is preferable (step 67). Either the first or second carrier 33 or 34 starts moving in response to an operation command from the carrier allocating unit 54.

(6) The operation according to the flowchart is completed when the operation command is issued by the carrier allocating unit 54 (step 68).

According to the second embodiment, the carrier control system 30 includes the rail 31 which extends in the shape of a closed loop and has the first and second rail tracks 311 and 312. The first and second carriers 33 and 34 move on the first and second rail tracks 311 and 312, respectively, without interfering with each other. Therefore, the first and second carriers 33 and 34 can operate in a variety of manners, e.g. they can get ahead of each other, or move in opposite directions. Even if one of the first and second carriers 33 and 34 remains stationary, the other carrier can move freely, which is effective in promoting acceleration or deceleration, alleviating traffic jam, reducing the delivery time, and improving delivery efficiency. As a result, the carrier system 30 can improve delivery and work efficiency.

Further, the control system 50 of the second embodiment includes the carrier position recognizing unit 51, destination recognizing unit 52, delivery time calculating unit 53, and carrier allocating unit 54, and controls the carriers 33 and 34 in order to lead them to the destinations 31a to 32l as quickly as possible. Therefore, the control system 50 can improve delivery and work efficiency.

With the carrier system 30 of the second embodiment, the rail 31 extends above the tables 35, and the first and second carriers 33 and 34 are suspended from the rail 31, and move on their associated rails. Alternatively, the first carrier 33 may move on a side surface of the rail 31 while the second carrier 34 may be moved above or below the first carrier 33. Further, the first and second carriers 33 and 34 may move on the upper surface of the rail 31. Still further, the tables 35 may be arranged beside the rail 31. The tables 35 may be positioned above the rail 31.

Finally, the carrier unit 30 may have the rail 31 extending straight similarly to the carrier system 1 of the first embodiment, so that the first and second carriers 33 and 34 reciprocate on the rail 31.

### OTHER EMBODIMENTS OF INVENTION

Although the invention has been described with respect to some preferred embodiments thereof, it will be understood by those skilled in the art that various modifications are possible without departing from the spirit of the present invention.

For instance, the carrier system 30 of the second embodiment may be the carrier system 1 of the first embodiment. In other words, the carrier system 30 may be constituted by a plurality of segmented carrier units. In such a case, the carrier system 30 and the control system 50 thereof are advantageous as the carrier system 1.

Further, the carrier system 30 may be provided with a third rail track in the rail 31. The third rail track is used to move a third carrier, in addition to the first and second carriers 33 and 34.

Still further, the present invention is applicable not only to the carrier systems 1 and 30, and the control system 50 which are used in the semiconductor manufacturing line, but also to carrier systems and control systems in printed circuit board (PCB) manufacturing lines, crystal quartz manufacturing lines, lines for manufacturing mechanical and electronic components, physical distribution lines, and so on.

The invention can provide the carrier system and carrier unit which can be operated with reduced labor and at a reduced cost.

Further, the invention can provide the carrier system and carrier unit which allow free replacement, increase, layout and so on of the railway, tables, manufacturing devices or the like and can be operated with reduced labor and at a reduced cost.

Still further, the invention can provide the carrier system and carrier unit which can speedily and efficiently delivery or retrieve objects.

The invention can provide the control system for enabling the carrier system to delivery and retrieve object speedily and efficiently.

The invention can provide the carrier unit, carrier system or control system which can accomplish tow or more effects mentioned above.

What is claimed is:

1. A carrier unit comprising at least:
a rail for moving a carrier thereon and having a predetermined unit length;
a table for placing an object and facing the rail; and
a coupler for joining the table to the rail.

2. The carrier unit of claim 1, wherein the unit length of the rail is equal to a width of the table.

3. The carrier unit of claim 1, wherein the rail is positioned above the table.

4. The carrier unit of claim 1, wherein the coupler joins the table to the rail in an integral manner.

5. The carrier unit of claim 1, wherein the coupler has one end thereof fastened to the rail and the other end thereof to the table by small screws, bolts and nuts, or by welding.

6. The carrier unit of claim 1 further comprising an inter-unit coupler for connecting a plurality of carrier units and rails.

7. The carrier unit of claim 6, wherein the inter-unit coupler includes a first inter-unit coupling of gibbosity and a second inter-unit coupling of trough.

8. The carrier unit of claim 1 further comprising a device-joint for joining to a manufacturing device.

9. The carrier unit of claim 1 further comprising a device-joint for joining to a manufacturing devices which form a semiconductor manufacturing line.

10. The carrier unit of claim 1, wherein the table is used for delivering and retrieving a semiconductor wafer container.

11. A carrier system comprising:
a plurality of carrier units each of which includes at least a rail for moving a carrier thereon and having a predetermined unit length, a table for placing an object and facing the rail, and a coupler for joining the table to the rail; and
an inter-unit joint for joining the carrier units and rails.

12. The carrier system of claim 11 further comprising a carrier moving on the plurality of rails having a grip for holding an object and a lift for moving the grip up and down.

13. The carrier system of claim 11 further comprising a device-joint for joining manufacturing device to the table of the carrier unit.

14. The carrier system of claim 11, wherein the rails extend in the shape of a closed loop.

15. The carrier system of claim 11, wherein the rails extend straight.

16. A carrier system comprising:
a rail including first rail track and second rail track which are independent;
a first carrier moving on the first rail track; and
a second carrier moving on the second rail track without interfering with the first carrier.

17. The carrier system of claim 16, wherein at least the first or second carrier includes a grip for holding an object and a lift for moving the grip up and down.

18. A control system for a carrier system comprising:
a rail including first rail track and second rail track which are independent;
a first carrier moving on the first rail track;
a second carrier moving on the second rail track without interfering with the first carrier;
a carrier position recognizing unit for recognizing positions of the first carrier on the first rail track and the second carrier on the second rail track;
a destination recognizing unit for recognizing destinations of the carriers;
a delivery time calculating unit for calculating a time for the first and second carriers to reach destinations; and
a carrier allocating unit for controlling the movement of the first or second carrier, which is advantageous on the basis of the calculated delivery time, to and from the destination.

19. The control system of claim 18, wherein the first and second carriers are moved in at least one of the following modes (1) to (5):
(1) both the first and second carriers are moved in the same direction;
(2) the first and second carriers are moved in opposite directions;
(3) either the first or second carrier is dedicated for delivery while the other carrier is dedicated for retrieval;
(4) either the first or second carrier is used for urgent delivery while the other carrier is used for normal delivery; and
(5) the first and second carriers are independently accelerated or decelerated.

20. The control system of claim 18 further comprising a host computer for controlling the carrier position recognizing unit, destination recognizing unit, delivery time calculating unit and carrier allocating unit.
